(19) United States
(12) Patent Application Publication
(10) Pub. No.: US 2026/0040546 A1
(43) Pub. Date: Feb. 5, 2026

(54) MEMORY DEVICE AND MANUFACTURING METHOD OF THE MEMORY DEVICE

(71) Applicant: SK hynix Inc., Icheon-si Gyeonggi-do (KR)

(72) Inventor: Do Young KIM, Icheon-si Gyeonggi-do (KR)

(73) Assignee: SK hynix Inc., Icheon-si Gyeonggi-do (KR)

(21) Appl. No.: 19/053,978

(22) Filed: Feb. 14, 2025

(30) Foreign Application Priority Data
Aug. 5, 2024 (KR) 10-2024-0103691

(51) Int. Cl. H10B 43/27; H10B 43/40

(52) U.S. Cl. CPC H10B 43/27; H10B 43/40

(57) ABSTRACT

A memory device includes a stack structure including conductive layers alternately stacked with interlayer insulting layers in a first direction, a channel layer extending through the stack structure, and charge trap patterns located between the channel layer and the conductive layers and spaced apart in the first direction. A side surface of a first charge trap pattern among the charge trap patterns has a first slope with respect to the first direction, the channel layer includes a first section extending in the first direction and a second section having the first slope, the first section of the channel layer includes a first impurity, and the second section of the channel layer includes a second impurity.

### CROSS-REFERENCE TO RELATED APPLICATION

The present application claims priority under 35 U.S.C. § 119 (a) to Korean patent application number 10-2024-0103691 filed on Aug. 5, 2024, in the Korean Intellectual Property Office, the entire contents of which application is incorporated herein by reference.

### BACKGROUND

### 1. Technical Field

The present disclosure generally relate to memory devices and methods of manufacturing the memory device, including but not limited to a memory device including a memory block having a three-dimensional structure and a method of manufacturing the memory device.

### 2. Related Art

Memory devices include non-volatile memory devices that retain stored data in the absence of a power supply. Non-volatile memory devices include memory devices including two-dimensional structures and memory devices including three-dimensional structures. Memory cells of a non-volatile memory device having a two-dimensional structure are arranged in a single layer on a substrate. Memory cells of a non-volatile memory device having a three-dimensional structure are stacked in a vertical direction to the substrate. Because integration density of non-volatile memory devices having three-dimensional structures is greater than integration density of non-volatile memory devices having two-dimensional structures, a quantity of electronic devices including non-volatile memory devices having three-dimensional structure is increasing.

### SUMMARY

According to an embodiment, a memory device may include a stack structure including plurality of conductive layers alternately stacked with a plurality of interlayer insulting layers in a first direction, a channel layer extending through the stack structure, and a plurality of charge trap patterns located between the channel layer and the plurality of conductive layers and spaced apart in the first direction. A side surface of a first charge trap pattern among the plurality of charge trap patterns has a first slope with respect to the first direction, the channel layer includes a first section extending in the first direction and a second section having the first slope, the first section of the channel layer includes a first impurity, and the second section of the channel layer includes a second impurity.

According to an embodiment, a method of manufacturing a memory device may include forming, on a substrate, a stack structure including a plurality of sacrificial layers alternately stacked with a plurality of interlayer insulating layers in a first direction, forming an opening extending in the first direction in the stack structure, exposing inner surfaces of the plurality of sacrificial layers and inner surfaces of the plurality of interlayer insulating layers, forming a plurality of charge trap patterns spaced apart in the first direction, wherein a side surface of a first charge trap pattern among the plurality of charge trap patterns has a first slope with respect to the first direction, wherein each of the plurality of charge trap patterns is disposed between the inner surfaces of a different one of the plurality of sacrificial layers in the first direction, forming a channel layer extending in the first direction between the inner surfaces of the plurality of sacrificial layers and the inner surfaces of plurality of interlayer insulating layers, wherein the channel layer includes a first section extending in the first direction and a second section having the first slope, injecting a first impurity into the first section of the channel layer, and injecting a second impurity into the second section of the channel layer, wherein the second impurity is different from the first impurity.

According to an embodiment, a memory device may include a stack structure including a plurality of conductive layers alternately stacked with a plurality of interlayer insulting layers in a first direction; a channel layer extending through the stack structure and including a first section including a first impurity and extending in the first direction and a second section including a second impurity and disposed at a first slope with relative to the first direction; and a charge trap pattern located between the channel layer and a first conductive layer of the plurality of conductive layers, wherein a side surface of the charge trap pattern is parallel to the second section.

### BRIEF DESCRIPTION OF THE DRAWINGS

FIG. 1 is a diagram illustrating a memory device according to an embodiment of the present disclosure;

FIG. 2 is a circuit diagram illustrating a memory block according to an embodiment of the present disclosure;

FIG. 3A is a cross-sectional view illustrating a structure of a memory device according to an embodiment of the present disclosure;

FIG. 3B is a diagram illustrating a concentration of impurities injected into a channel layer of a memory device according to an embodiment of the present disclosure;

FIG. 4A, 4B, 4C, 4D, 4E, 4F, 4G, 4H, 4I, 4J, 4K, 4L, and 4M are diagrams illustrating a memory device formed utilizing a method of manufacturing the memory device according to an embodiment of the present disclosure;

FIG. 5 is a diagram illustrating a memory card system including a memory device according to an embodiment of the present disclosure; and

FIG. 6 is a diagram illustrating a solid state drive (SSD) system including a memory device according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

Terms such as “vertical,” “horizontal,” “top,” “bottom,” “above,” “under,” “over,” “on,” “side,” “upper,” “lower,” “lowermost,” “upward,” “higher,” “low,” “left,” “column,” “row,” “level,” and other terms implying relative spatial relationship or orientation are utilized only for the purpose of ease of description or reference to a drawing and are not otherwise limiting.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements. When one element is identified as “on,” “over,” “under,” or “beneath” another element, the elements may directly contact each other or an intervening element may be disposed between the elements.

A memory device capable of improving the performance of a select transistor and a method of manufacturing the memory device are disclosed.

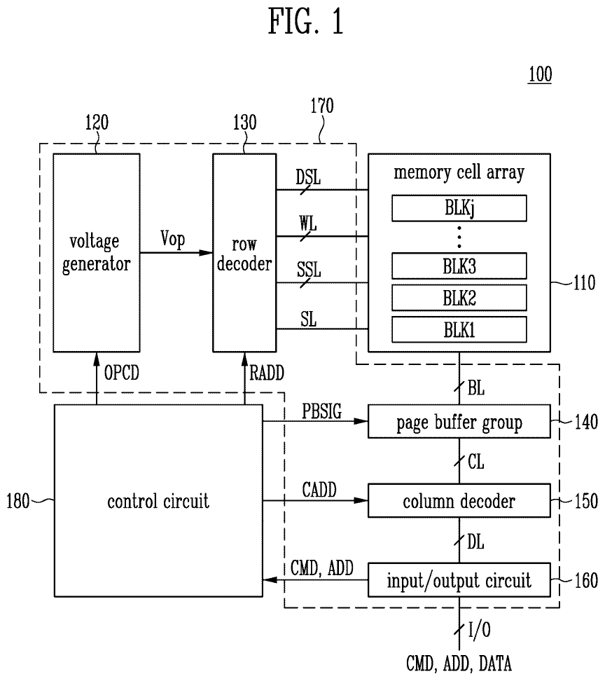

FIG. 1 is a diagram illustrating a memory device 100 according to an embodiment of the present disclosure.

Referring to FIG. 1, the memory device 100 includes a memory cell array 110, a peripheral circuit 170, and a control circuit 180.

The memory cell array 110 include a first memory block BLK1 to a jth memory block BLKj. Each of the memory blocks BLK1 to BLKj includes memory cells capable of storing data. Drain select lines DSL, word lines WL, source select lines SSL, and a source line SL are coupled to each of the memory blocks BLK1 to BLKj, and bit lines BL are commonly coupled to the first to jth memory blocks BLK1 to BLKj.

Each of the memory blocks BLK1 to BLKj has a three-dimensional structure. Memory blocks having a three-dimensional structure include memory cells stacked in a vertical direction on a substrate. Select transistors may be disposed above and under the memory cells stacked in the vertical direction. For example, a drain select transistor may be disposed above the memory cells and a source select transistor may be disposed under the memory cells.

The memory cells store one bit or two or more bits of data according to a program method. For example, a method in which one-bit data is stored in one memory cell is referred to as a single-level cell (SLC) method, and a method in which two-bit data is stored in one memory cell is referred to as a multi-level cell (MLC) method. A method in which three-bit data is stored in one memory cell is referred to as a triple-level cell (TLC) method, and a method in which four-bit data is stored in one memory cell is referred to as a quad-level cell (QLC) method. Five or more bits of data may be stored in one memory cell.

The peripheral circuit 170 is configured to perform a program operation that stores data in the memory cell array 110, a read operation that outputs data stored in the memory cell array 110, and an erase operation that erases data stored in the memory cell array 110. For example, the peripheral circuit 170 includes a voltage generator 120, a row decoder 130, a page buffer group 140, a column decoder 150, and an input/output circuit 160.

The voltage generator 120 generates various operating voltages Vop used during any of a program operation, a read operation, and an erase operation in response to an operation code OPCD. For example, the voltage generator 120 is configured to generate program voltages, turn-on voltages, turn-off voltages, negative voltages, pre-charge voltages, verify voltages, read voltages, pass voltages, and erase voltages in response to the operation code OPCD. The operating voltages Vop generated by the voltage generator 120 are applied to the drain select lines DSL, the word lines WL, the source select lines SSL, and the source line SL of a selected memory block by the row decoder 130.

The program voltages are applied to a selected word line among the word lines WL during a program operation and are used to increase threshold voltages of memory cells coupled to the selected word line. The turn-on voltages are applied to the drain select lines DSL or the source select lines SSL and are used to turn on the drain select transistors and the source select transistors. The turn-off voltages are applied to the drain select lines DSL and the source select lines SSL and are used to turn off the drain select transistors or the source select transistors. For example, the turn-off voltages may be 0 V. The pre-charge voltages may be higher than 0 V and are applied to the bit lines BL during a read operation. The verify voltages are used during a verify operation to determine whether threshold voltages of selected memory cells are increased to a target level. The verify voltages may be at various levels according to the target level and are applied to the selected word line.

The read voltages are applied to the selected word line during a read operation of the selected memory cells. For example, the read voltages may be at to various levels according to a program method of the selected memory cells. The pass voltages are applied to unselected word lines among the word lines WL during a program or read operation and are used to turn on memory cells coupled to the unselected word lines. The erase voltages are used during an erase operation to erase memory cells included in the selected memory block and are applied to the source line SL.

The row decoder 130 is configured to transfer the operating voltages Vop to the drain select lines DSL, the word lines WL, the source select lines SSL, and the source line SL that are coupled to a memory block selected according to a row address RADD. For example, the row decoder 130 is coupled to the voltage generator 120 through global lines and is coupled to the memory blocks BLK1 to BLKj through the drain select lines DSL, the word lines WL, the source select lines SSL, and the source line SL.

The page buffer group 140 includes page buffers (not shown) respectively coupled to the memory blocks BLK1 to BLKj. The page buffers are coupled to the memory blocks BLK1 to BLKj through corresponding bit lines BL. During a read operation, the page buffers, in response to page buffer control signals PBSIG, sense a current or a voltage of the bit lines BL, which current or voltage varies according to the threshold voltages of the selected memory cells and temporarily stores sensed data.

The column decoder 150 is configured to facilitate transfer of data between the page buffer group 140 and the input/output circuit 160 in response to a column address CADD. For example, the column decoder 150 is coupled to the page buffer group 140 through column lines CL and transfers enable signals through the column lines CL. The page buffers included in the page buffer group 140 receive or output data through data lines DL in response to the enable signals.

The input/output circuit 160 is configured to receive or output a command CMD, an address ADD, or data through input/output lines I/O. For example, the input/output circuit 160 transfer the command CMD and the address ADD, received from an external controller through the input/output lines I/O, to the control circuit 180 and transfers data DATA, received from the external controller through the input/output lines I/O, to the page buffer group 140. Alternatively, the input/output circuit 160 outputs data DATA transferred from the page buffer group 140 to the external controller through the input/output lines I/O.

The control circuit 180 outputs at least one of the operation code OPCD, the row address RADD, the page buffer control signals PBSIG, and the column address CADD in response to the command CMD and the address ADD. For example, when the command CMD input to the control circuit 180 corresponds to a program operation, the control circuit 180 controls the peripheral circuit 170 to perform the program operation on a memory block selected by the address ADD. When the command CMD input to the control circuit 180 corresponds to a read operation, the control circuit 180 controls the peripheral circuit 170 to perform the read operation on the memory block selected by the address ADD and to output read data. When the command CMD input to the control circuit 180 corresponds to an erase operation, the control circuit 180 controls the peripheral circuit 170 to perform the erase operation on the selected memory block.

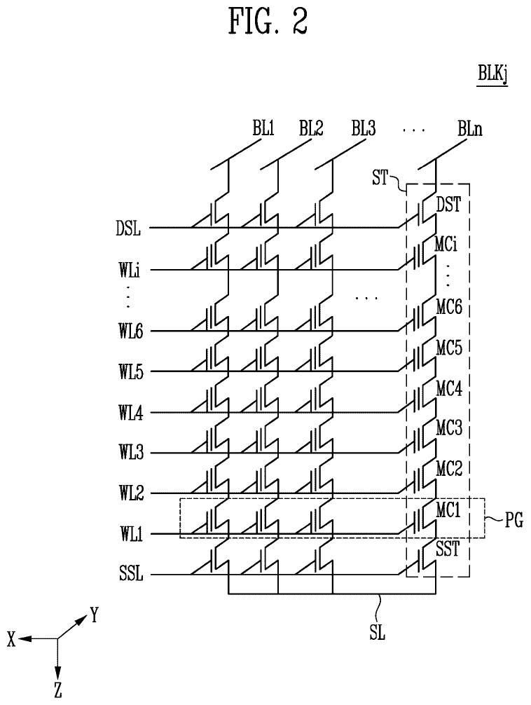

FIG. 2 is a circuit diagram illustrating a memory block according to an embodiment of the present disclosure.

The memory blocks BLK1 to BLKj as shown in FIG. 1 may have a similar configuration. FIG. 2 shows the jth memory block BLKj as an example among the first memory block BLK1 to the jth memory block BLKj.

Referring to FIG. 2, the jth memory block BLKj includes strings ST that couple a first bit line BL1 to an nth bit line BLn and the source line SL. The bit lines BL1 to BLn extend in a Y direction and are spaced apart in an X direction. The strings ST that extend in a Z direction are spaced apart in the X and Y directions.

One of the strings ST coupled to the nth bit line BLn is described in an example. The string ST includes a source select transistor SST, memory cells MC1 to MCi, and a drain select transistor DST. Although FIG. 2 shows the jth memory block BLKj and illustrates the connecting configuration of the memory block, the quantity of source select transistors SST, the quantity of first to ith memory cells MC1 to MCi, and the quantity of drain select transistors DST may vary depending on memory devices. For example, the string ST may include two or more source select transistors SST or two or more drain select transistors DST.

Gates of the source select transistors SST included in different strings ST are coupled to the source select line SSL. Gates of the memory cells MC1 to MCi included in different strings ST are coupled to word lines WL1 to WLi, respectively. Gates of the drain select transistors DST included in different strings ST are coupled to the drain select line DSL.

Memory cells included in the same level among the memory cells MC1 to MCi are coupled to the same word line. For example, the first memory cells MC1 included in different strings ST is commonly coupled to the first word line WL1, and the ith memory cells MCi included in different strings ST is commonly coupled to the ith word line WLi. A group of memory cells included in different strings ST and coupled to the same word line form a page PG. A program operation and a read operation are performed in units of pages PG, and an erase operation is performed in units of memory blocks.

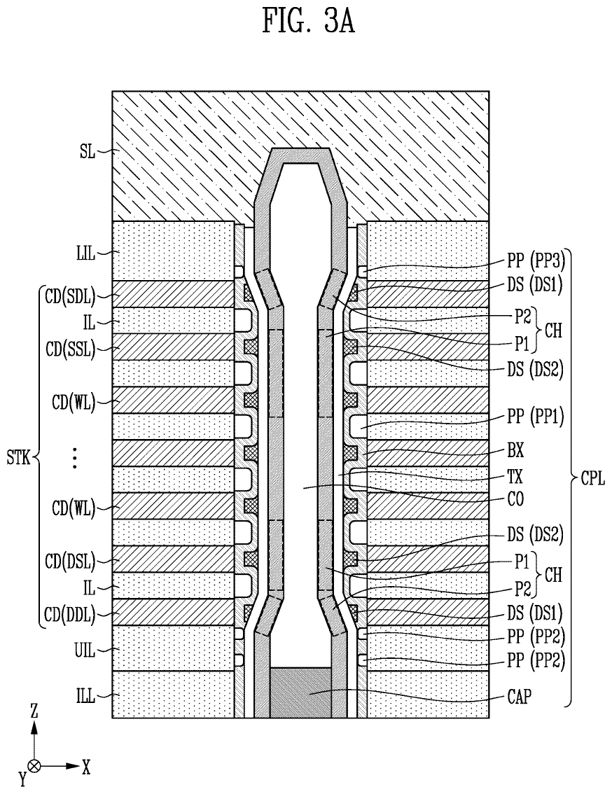

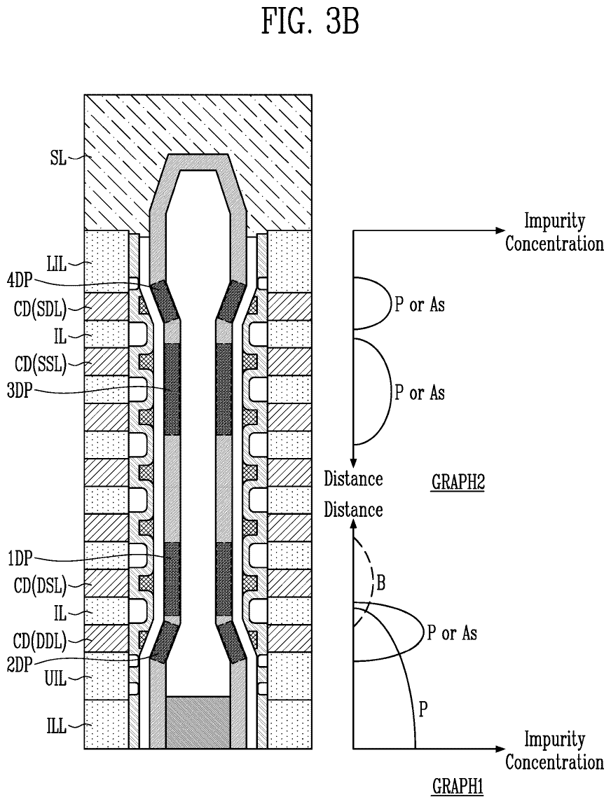

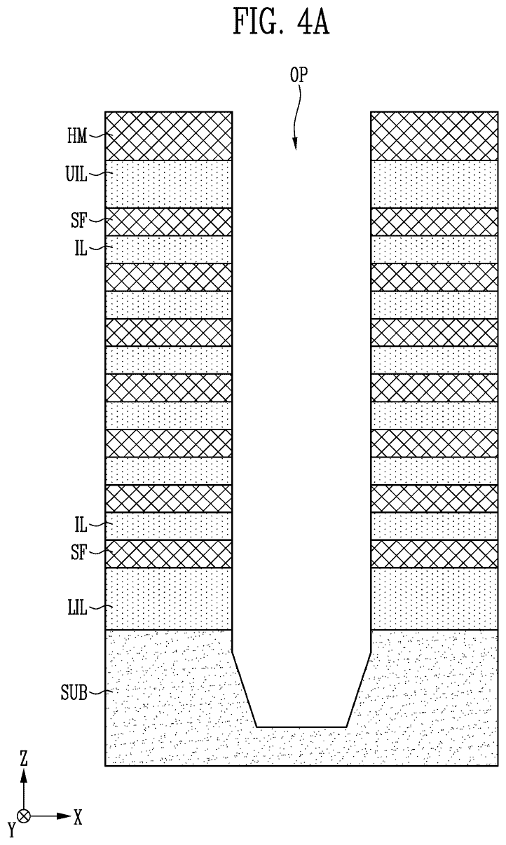

FIG. 3A is a cross-sectional view illustrating a structure of a memory device according to an embodiment of the present disclosure.

A cell plug CPL as shown in FIG. 3A corresponds to any one of the strings ST included in any one memory block among the memory blocks BLK1 to BLKj shown in FIG. 1. For example, the source select transistor SST, the memory cells MC1 to MCi, and the drain select transistor DST described with reference to FIG. 2 are formed at corresponding intersections of the cell plug CPL and conductive layers CD in FIG. 3A.

Referring to FIG. 3A, a stack structure STK includes the conductive layers CD alternately stacked with interlayer insulating layers IL along a Z axis. The conductive layers CD are insulated from each other by the interlayer insulating layers IL. One of the interlayer insulating layers IL is located between consecutive conductive layers CD.

The conductive layers CD include the source select line SSL, the word lines WL, and the drain select line DSL described with reference to FIG. 1 and FIG. 2. The conductive layers CD include dummy lines SDL and DDL. For example, a conductive layer CD located farther in the Z direction than the source select line SSL, among the conductive layers CD, is a source dummy line SDL. A conductive layer CD below the drain select line DSL in the Z direction is a drain dummy line DDL. The dummy lines SDL and DDL are controlled to float during a program operation or an erase operation. Alternatively, the dummy lines SDL and DDL are controlled to operate with the unselected word lines by applying a read bias, for example, 0 to 10 V, to the dummy lines SDL and DDL during a program operation or an erase operation.

The quantity of the stacked conductive layers CD shown in FIG. 3A is an example, and the present disclosure is not limited to the embodiment shown in FIG. 3A. For example, the quantity of stacked dummy lines SDL and DDL may be greater than the quantity shown in FIG. 3A, the quantity of the stacked select lines SSL and DSL may be greater than as the quantity shown in FIG. 3A, and/or the quantity of stacked word lines WL may be greater than the quantity shown in FIG. 3A. The quantity of stacked source dummy lines SDL may be equal to or different than the quantity of stacked drain dummy lines DDL, and the quantity of stacked source select lines SSL may be equal to or different than the quantity of stacked drain select lines DSL.

The memory device includes an upper insulating layer UIL under the stack structure STK. The memory device includes a lower insulating layer LIL over or on the stack structure STK. The memory device includes an insulating layer ILL under the upper insulating layer UIL. For example, the insulating layer ILL may be a hard mask or a layer that replaces the hard mask. Because the memory device of the present disclosure has a wafer bonding structure, the upper insulating layer UIL is located under the stack structure STK and the lower insulating layer LIL is located over the stack structure STK.

The conductive layers CD may include a conductive material. For example, the conductive layers CD may include at least one of tungsten (W), cobalt (Co), nickel (Ni), molybdenum (Mo), silicon (Si), and polysilicon (poly-Si).

The interlayer insulating layers IL may include an insulating material. For example, the interlayer insulating layers IL may include an oxide layer. The interlayer insulating layers IL may include a silicon oxide layer or an oxide material corresponding thereto. The upper insulating layer UIL and the lower insulating layer LIL may include the same materials as the interlayer insulating layers IL. Each of the upper insulating layer UIL and the lower insulating layer LIL may include a silicon oxide layer or a corresponding oxide material. The insulating layer ILL may include an oxide layer or a nitride layer.

The memory device includes the cell plug CPL. The cell plug CPL extends in the Z direction. The cell plug CPL extends through the stack structure STK. The cell plug CPL extends through the conductive layers CD and the interlayer insulating layers IL. The cell plug CPL extends through the lower insulating layer LIL, the upper insulating layer UIL, and the insulating layer ILL in the example of FIG. 3A.

The cell plug CPL includes protruding patterns PP. The protruding patterns PP are spaced apart in the Z direction. The protruding patterns PP may have a ring shape in the X-Y plane. An inner wall of the protruding patterns PP, which inner wall is a closest feature of the protruding patterns PP to a center of the cell plug, may be a convex surface.

The protruding patterns PP include first protruding patterns PP1, second protruding patterns PP2, and a third protruding pattern PP3. The first protruding patterns PP1 protrude from side surfaces of the interlayer insulating layers IL radially toward a center of the cell plug, which is a horizontal or X direction in the cross-section of FIG. 3A. The second protruding patterns PP2 protrude from a side surface of the upper insulating layer UIL radially toward a center of the cell plug, which is the horizontal direction in the cross-section of FIG. 3A. The second protruding patterns PP2 are spaced apart along the side surface of the upper insulating layer UIL in the Z direction. The third protruding pattern PP3 protrude from a side surface of the lower insulating layer LIL radially toward a center of the cell plug, which is the horizontal direction in the cross-section of FIG. 3A.

Each of the first protruding patterns PP1 may have a same size and shape. The height of each of the first protruding patterns PP1 in the Z direction may be the same as or shorter than the height of each of the interlayer insulating layers IL in the Z direction. For example, the height of each of the first protruding patterns PP1 in the Z direction may be equal to the height of each of the interlayer insulating layers IL in the Z direction. Alternatively, the height of each of the first protruding patterns PP1 in the Z direction may be smaller or larger by a predetermined amount than the height of each of the interlayer insulating layers IL in the Z direction. The lengths of each of the first protruding patterns PP1 in the radial direction may be equal or similar.

The sizes and shapes of the second protruding patterns PP2 and the third protruding patterns PP3 are different from size and shape of the first protruding patterns PP1. Each of the protruding patterns PP2 and PP3 is smaller than each of the first protruding patterns PP1. For example, the heights of each of the second protruding patterns PP2 and the third protruding pattern PP3 are shorter than the heights of each of the first protruding patterns PP1 in the Z direction, and the lengths of each of the second protruding patterns PP2 and the third protruding pattern PP3 are shorter than the lengths of each of the first protruding patterns PP1 in the radial direction, such as the horizontal direction in FIG. 3A. The third protruding pattern PP3 may have a similar size and shape as the second protruding pattern PP2. Alternatively, the third protruding pattern PP3 may be larger or smaller than each of the second protruding patterns PP2.

The protruding patterns PP may include an insulating material. For example, the protruding patterns PP may include an oxide layer. The protruding patterns PP may include a silicon oxide layer or an oxide material corresponding thereto.

The cell plug CPL includes a blocking insulating layer BX that extends along surfaces of the protruding patterns PP. The blocking insulating layer BX is formed on the surfaces of the protruding patterns PP and surfaces of the conductive layers CD. The blocking insulating layer BX is formed in a conformal manner on the surfaces of the protruding patterns PP, for example, the first protruding patterns PP1, and the surfaces of the conductive layers CD. The blocking insulating layer BX may have a serpentine structure that alternates curving inwardly and outwardly along to the protruding patterns PP. The blocking insulating layer BX includes convex sections closer to the center of the cell plug CPL and concave sections adjacent to the protruding patterns PP.

A section of the blocking insulating layer BX may not cover all surfaces of the protruding patterns PP, for example, the second protruding patterns PP2 and the third protruding pattern PP3. For example, the convex surfaces of the second protruding patterns PP2 and the third protruding pattern PP3 contact the tunneling layer TX, and the blocking insulating layer BX does not cover the areas of the protruding patterns PP2 and PP3 that contact the tunneling layer TX. Because each of the second and third protruding patterns PP2 and PP3 has a smaller volume than the first protruding patterns PP1, a section of the blocking insulating layer BX that contacts the second and third protruding patterns PP2 and PP3 may not have a concave or convex structure. Alternatively, unlike the embodiment shown in FIG. 3A, the blocking insulating layer BX may be conformally formed on the outer surfaces of the protruding patterns PP2 and PP3.

The blocking insulating layer BX may include an insulating material. For example, the blocking insulating layer BX may include an oxide layer. The blocking insulating layer BX may include a silicon oxide layer, a silicon oxynitride layer, or an oxide material corresponding thereto.

The cell plug CPL includes charge trap patterns DS located between the protruding patterns PP. Each charge trap pattern DS is located between the consecutive protruding patterns PP that are spaced apart in the Z direction. The charge trap patterns DS are located at the same levels or heights as the conductive layers CD in the Z direction. Each of the charge trap patterns DS is located in the horizontal direction across from one of the conductive layers CD. Each charge trap patterns DS is surrounded by one of the conductive layers CD. Each of the charge trap patterns DS may have a ring shape. For example, each of the charge trap patterns DS may have a ring shape which surrounds a channel layer CH.

The charge trap patterns DS are formed in the concave sections of the blocking insulating layer BX. The blocking insulating layer BX extends between the protruding patterns PP and the charge trap patterns DS. For example, the blocking insulating layer BX and the charge trap pattern DS are located between the protruding patterns PP that are consecutively arranged in the Z direction. The protruding patterns PP and the charge trap patterns DS are separated from each other by the blocking insulating layer BX.

The charge trap patterns DS are separated from each other in the Z direction between the protruding patterns PP. Each of the charge trap patterns DS is located between consecutive protruding patterns PP. The charge trap patterns DS are alternately arranged with the protruding patterns PP in the Z direction. The charge trap patterns DS that are consecutively arranged in the Z direction are separated from each other by the blocking insulating layer BX and the protruding pattern PP. Because the charge trap patterns DS formed at different levels in the Z direction are not coupled to each other but are separated from each other, negative charges trapped in the charge trap patterns DS during a program operation do not move to consecutive charge trap patterns DS that are located successively in the vertical direction. Retention characteristics of the memory device may be improved by separation of the charge trap patterns DS in the Z direction, and the reliability of the memory device may be improved.

The charge trap patterns DS include first charge trap patterns DS1 and second charge trap patterns DS2. The first charge trap patterns DS1 are located in the horizontal direction across from conductive layers CD corresponding to the dummy lines SDL and DDL. The second charge trap patterns DS2 are located in the horizontal direction across from the conductive layers CD corresponding to the select lines SSL and DSL and the word lines WL.

The first charge trap patterns DS1 have a different shape from the second charge trap patterns DS2. Inner surfaces of the second charge trap patterns DS2 are parallel to the Z direction. Inner surfaces of the first charge trap patterns DS1 are inclined or angled with relative to the Z direction. Inner surfaces of the first charge trap patterns DS1 are surfaces closest to the center of the cell plug CPL. For example, the first charge trap pattern DS1 located in the horizontal direction across from the drain dummy line DDL have a first slope or angle with relative to the Z direction and the X direction.

The shape of the charge trap patterns DS is determined by the sizes and the shapes of the protruding patterns PP located nearest to a respective charge trap pattern DS. Because the second charge trap patterns DS2 are located between the first protruding patterns PP1 that have equal sizes and similar shapes, a space where the second charge trap patterns DS2 is located has a symmetrical shape in the Z direction. The inner surfaces of the second charge trap patterns DS2 are parallel to the Z direction. Inner surfaces of the second charge trap patterns DS2 are surfaces closest to the center of the cell plug CPL. The first charge trap patterns DS1 are located between a first protruding pattern PP1 and a second protruding pattern PP2 or between a first protruding pattern PP1 and a third protruding pattern PP3. Because the second protruding patterns PP2 and the third protruding patterns PP3 are smaller in size than the first protruding patterns PP1, a space where the first charge trap patterns DS1 is located has an asymmetric shape in the Z direction. The first charge trap patterns DS1 have a triangular or trapezoidal cross-section.

The charge trap patterns DS may include a nitride layer. For example, the charge trap patterns DS may include a silicon nitride layer.

The cell plug CPL includes a tunneling layer TX that contacts the charge trap patterns DS and the blocking insulating layer BX. The tunneling layer TX may contact the charge trap patterns DS at levels corresponding to the conductive layers CD. In addition, the tunneling layer TX may contact the blocking insulating layer BX at levels corresponding to the interlayer insulating layers IL. Further, the tunneling layer TX may contact the second and third protruding patterns PP2 and PP3 at levels corresponding to the lower insulating layer LIL and the upper insulating layer UIL.

The tunneling layer TX is conformally formed on the blocking insulating layer BX and the charge trap patterns DS. Because the second protruding patterns PP2 and the third protruding patterns are smaller in size than the first protruding patterns PP1, and the first charge trap patterns DS1 have inclined inner surfaces, the tunneling layer TX includes inclined sections relative to the Z direction. For example, the tunneling layer TX has a cylindrical shape extending in the Z direction between the select lines SSL and DSL, the word lines WL, and the upper and lower insulating layers UIL and LIL and a cone shape inclined relative to the Z direction at levels corresponding to the dummy lines SDL and DDL.

The tunneling layer TX may include an insulating material. For example, the tunneling layer TX may include an oxide layer. The tunneling layer TX may include a silicon oxide layer or an oxide material corresponding thereto.

The cell plug CPL includes the channel layer CH that contacts an inner surface of the tunneling layer TX. An outer surface of the channel layer CH contacts the inner surface of the tunneling layer TX. The tunneling layer TX surrounds a side surface of the channel layer CH. The channel layer CH extends through the stack structure STK. The channel layer CH may include an undoped silicon layer or a doped silicon layer.

The channel layer CH is conformally formed on the inner surface of the tunneling layer TX. The channel layer CH includes first sections P1 extending in the Z direction and second sections P2 inclined or angled with respect to the Z direction. The first sections P1 are located at levels, in the Z direction, corresponding to the select lines SSL and DSL and the word lines WL. The second sections P2 are located at levels, in the Z direction, corresponding to the dummy lines SDL and DDL. The second sections P2 are located in the horizontal direction across from the first charge trap patterns DS1. The second section P2 have a second slope corresponding to the first slope of the inner surface of each of the first charge trap patterns DS1. The second sections P2 may be parallel to the inner surface of the first charge trap patterns DS1. The second slope is equal to the first slope, or smaller or greater by a percentage than the first slope. The first sections P1 has a cylindrical shape extending in the Z direction. The second sections P2 have a cone shape inclined with respect to the Z direction. A diameter of the second section P2 is greater than a diameter of the first section P1 in the X-Y plane. For example, the shortest distance between the second section P2 of the channel layer CH and the stack structure STK is smaller than the distance between the first section P1 of the channel layer CH and the stack structure STK.

The cell plug CPL may include a core pillar CO disposed within the walls of the channel layer CH. The core pillar CO is surrounded by the channel layer CH. The core pillar CO has a cylindrical shape at levels corresponding to the first sections P1 of the channel layer CH and has a cone shape at a level, in the Z direction, corresponding to the second section P2 of the channel layer CH. The core pillar CO may include an insulating layer or a conductive layer.

The cell plug CPL includes a capping layer CAP disposed under the core pillar CO. The capping layer CAP contacts a lower surface of the core pillar CO and an inner surface of the channel layer CH. The capping layer CAP may include an undoped silicon layer or a doped silicon layer.

The memory device includes the source line SL disposed over the lower insulating layer LIL. The source line SL contacts a section of the channel layer CH. Though not shown in FIG. 3A, the memory device may include a bit line BL disposed under the insulating layer ILL. The bit line BL is electrically coupled to the channel layer CH and the capping layer CAP of the cell plug CPL.

FIG. 3B is a diagram illustrating a concentration of impurities injected into the channel layer CH of a memory device according to an embodiment of the present disclosure.

FIG. 3B illustrates various concentrations of impurities included in the channel layer CH shown in FIG. 3A along the Z direction. A first graph GRAPH1 of FIG. 3B shows concentrations and types of impurities depending on injection distances of the impurities in a region at levels corresponding the drain dummy line DDL and the drain select line DSL. A second graph GRAPH2 of FIG. 3B shows concentrations and types of impurities depending on injection distances of the impurities in a region at levels corresponding to the source dummy line SDL and the source select line SSL.

Referring to FIG. 3A and FIG. 3B, the first sections P1 of the channel layer CH correspond to a first doped region 1DP and a third doped region 3DP. For example, the doped regions 1DP and 3DP correspond to or include at least a segment of the first sections P1 of the channel layer CH. The second sections P2 of the channel layer CH correspond to a second doped region 2DP and a fourth doped region 4DP. For example, the second and fourth doped regions 2DP and 4DP correspond to or include at least a segment of the second sections P2 of the channel layer CH. With reference to FIG. 3B, the doped regions 1DP to 4DP, into which the sections P1 and P2 are subdivided, are described to focus on impurities injected into the various sections. The first and third doped regions 1DP and 3DP correspond to the first sections P1 of the channel layer CH, and the second and fourth doped regions 2DP and 4DP correspond to the second sections P2 of the channel layer CH.

Referring to the first graph GRAPH1 of FIG. 3B, the first doped region 1DP of the channel layer CH includes a first impurity and the second doped region 2DP of the channel layer CH includes a second impurity. Referring to the first graph GRAPH1, the first impurity and the second impurity are different types of impurities. The first impurity may correspond to an element of group 13 of the periodic table and the second impurity may correspond to an element of group 15 of the periodic table. Group 13 of the periodic table includes the elements boron (B), aluminum (Al), gallium (Ga), indium (In), thallium (Ti), and nihonium (Nh). Group 15 of the periodic table includes the elements nitrogen (N), phosphorus (P), arsenic (As), Antimony (Sb), bismuth (Bi), and moscovium (Mc). For example, the first doped region 1DP may include boron B and the second doped region 2DP may include phosphorus P or arsenic As. The resistance of the drain dummy line DDL is reduced because of the impurities injected into the first doped region 1DP and the second doped region 2DP of the channel layer CH, thereby improving the operation of the drain select transistor DST.

The first impurity, for example, boron B, injected into the first doped region 1DP is distributed at a level corresponding to the drain select line DSL. The second impurity, for example, phosphorus P or arsenic As, injected into the second doped region 2DP is distributed at a level corresponding to the drain dummy line DDL. According to a method of an impurity injection process, for example, energy, a depth at which each impurity is injected may vary.

The peak concentration of the first impurity, for example, boron B, injected into the first doped region 1DP may be lower than the peak concentration of the second impurity, for example, phosphorus P or arsenic As, injected into the second doped region 2DP. Alternatively, unlike the embodiment shown in FIG. 3B, the peak concentration of the first impurity, for example, boron B, injected into the first doped region 1DP may be similar to or higher than the peak concentration of the second impurity, for example, phosphorus P or arsenic As, injected into the second doped region 2DP. According to the method of the impurity injection process, for example, an angle or an injection dose, the distribution pattern and the concentration of each impurity may vary.

The first doped region 1DP may coincide with the second doped region 2DP. For example, as illustrated in the first graph GRAPH1, the first impurity, boron B, is injected in a region where the second impurity, phosphorus P or arsenic As, is also injected. In FIG. 3B, the first doped region 1DP is illustrated as spaced apart from the second doped region 2DP of the channel layer CH for simplicity of explanation. The first doped region 1DP and the second doped region 2DP of the channel layer CH may be wider than shown in the cross-sectional view.

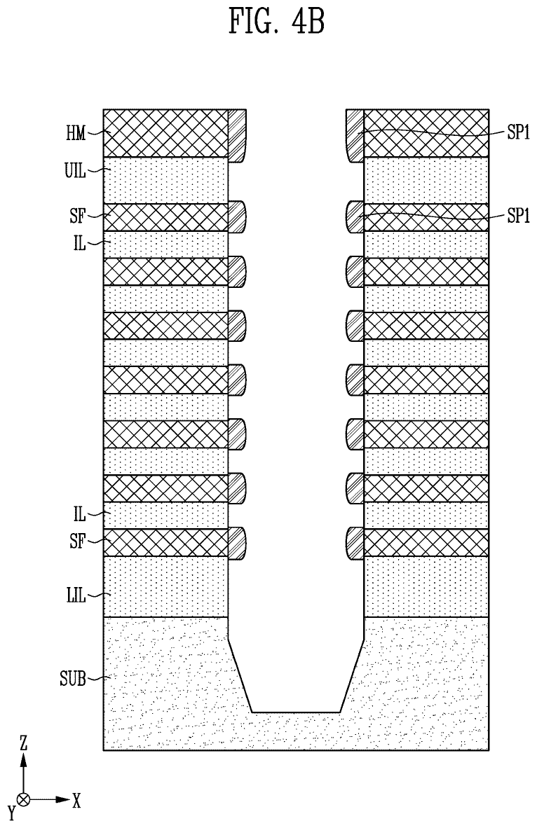

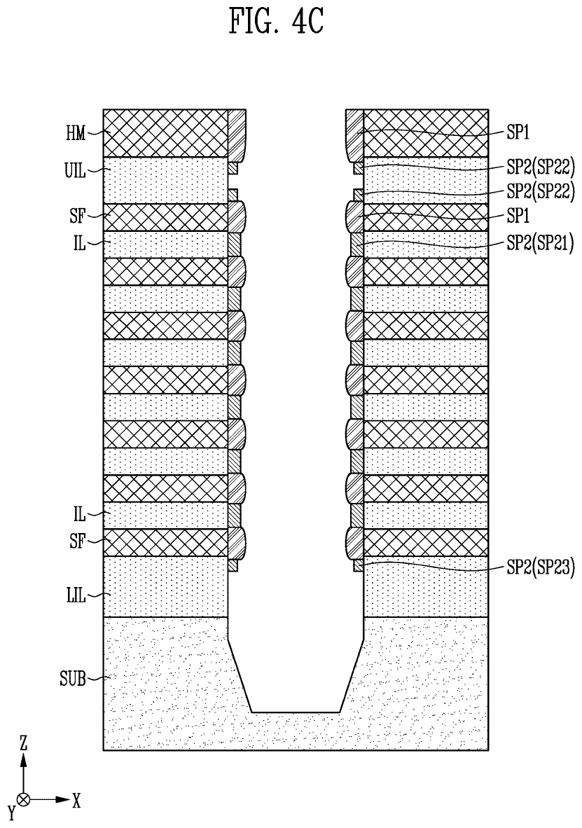

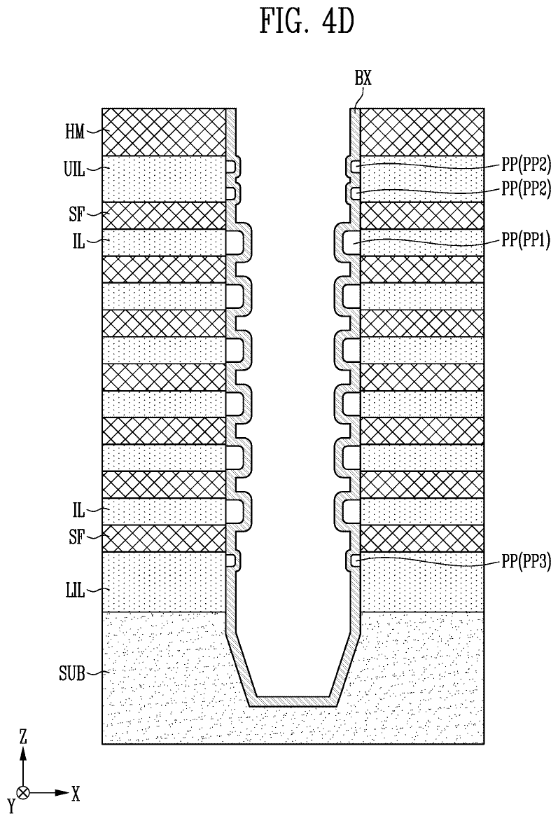

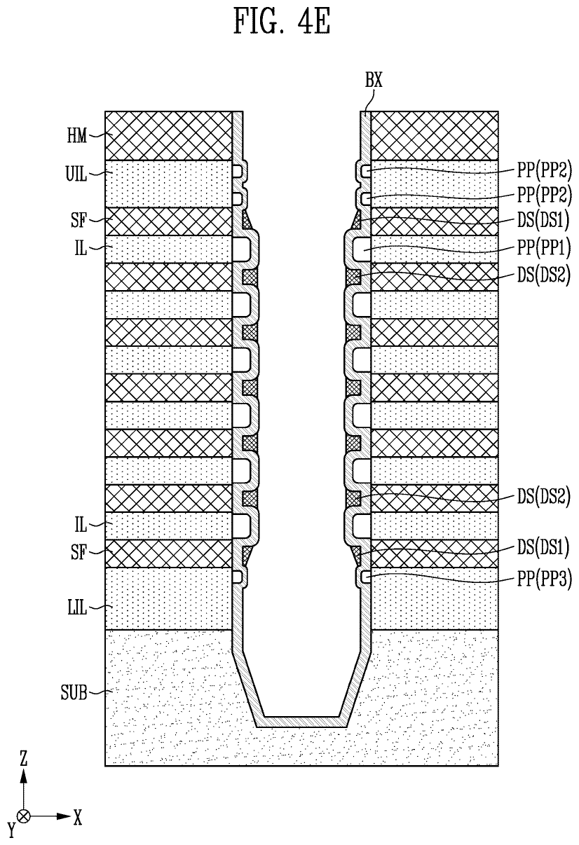

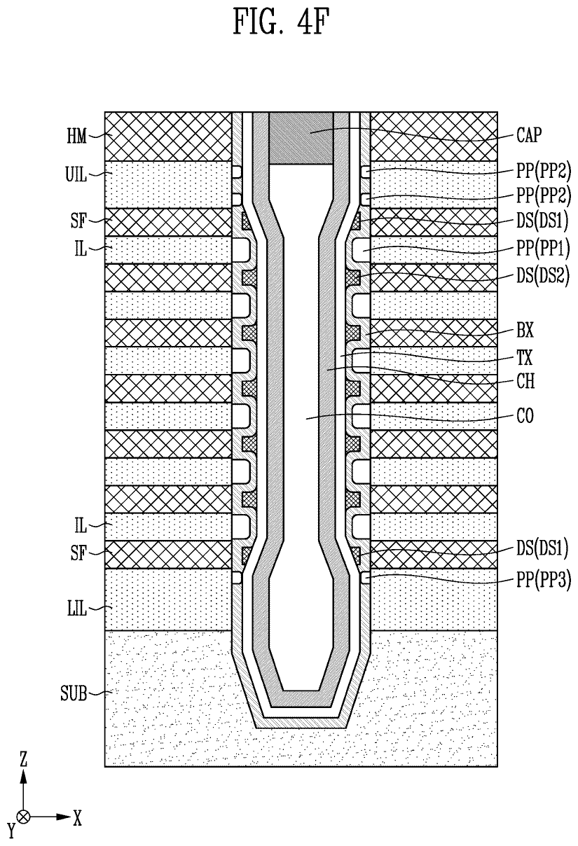

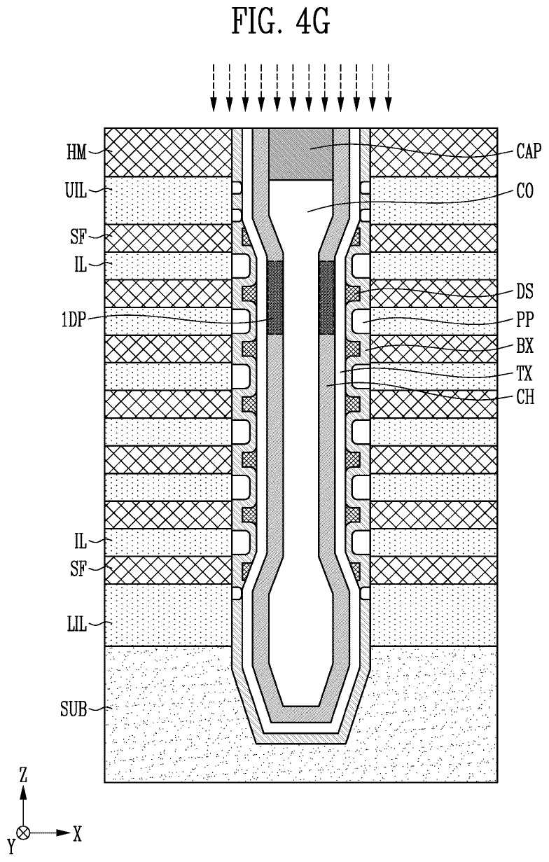

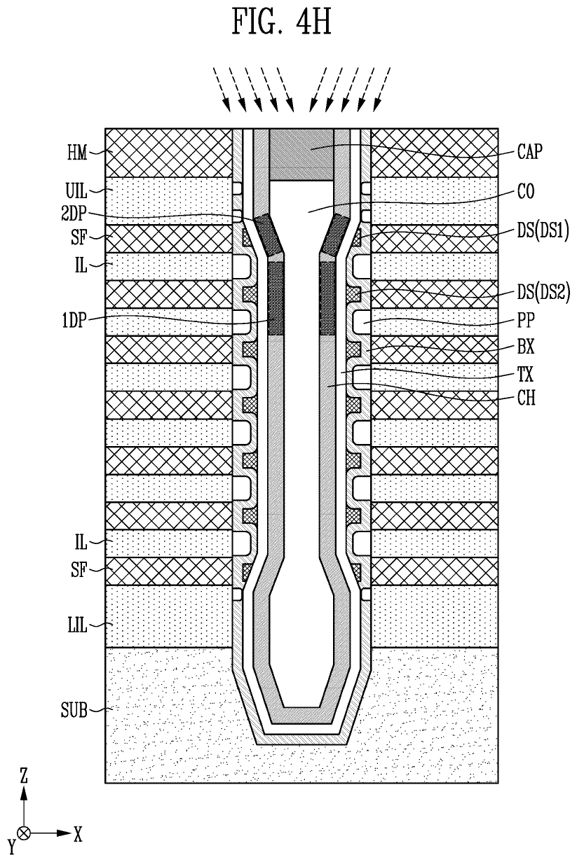

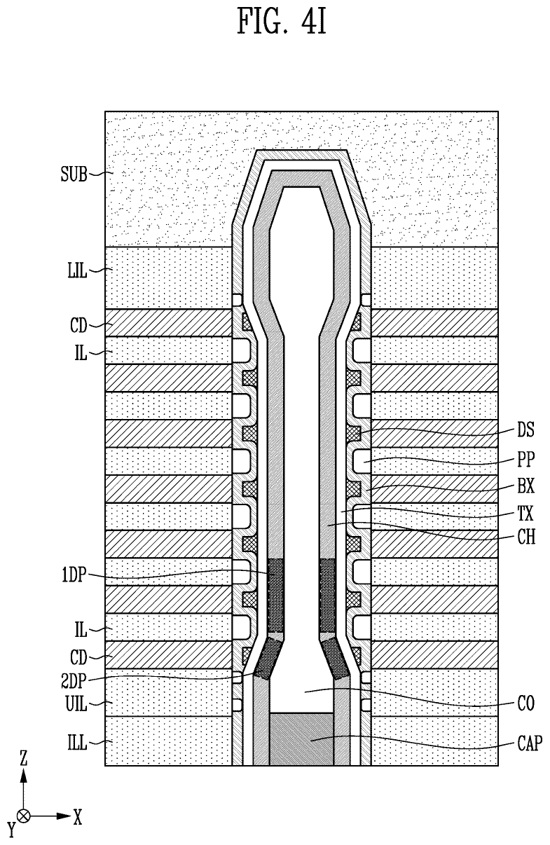

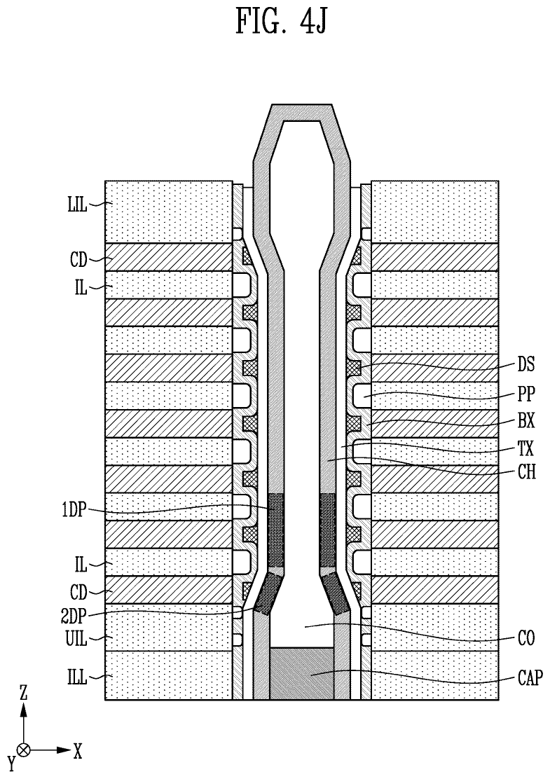

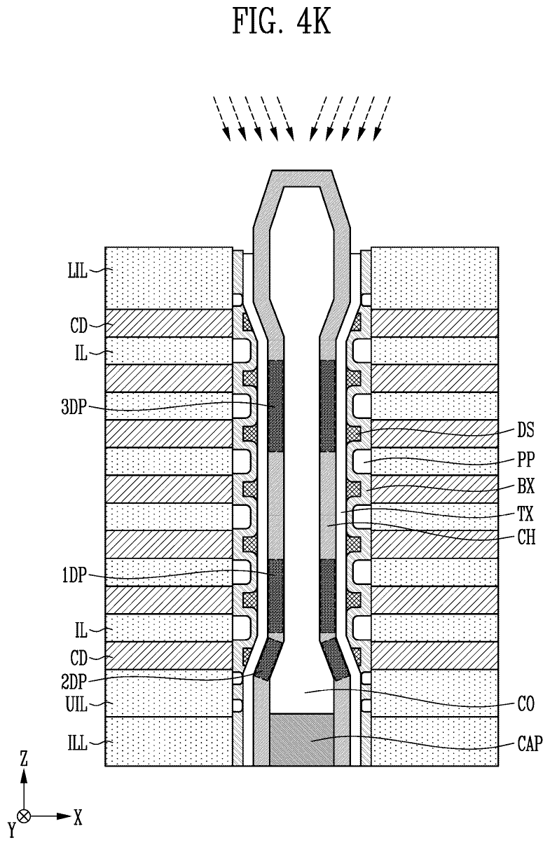

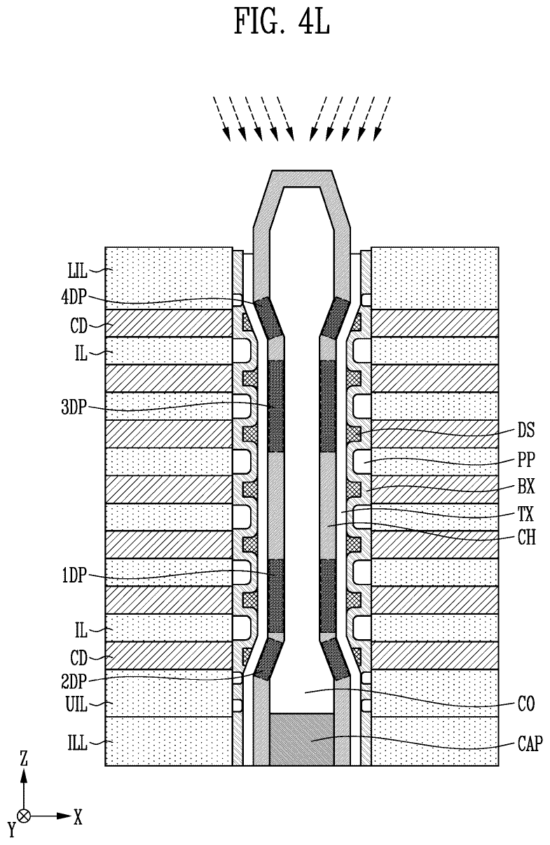

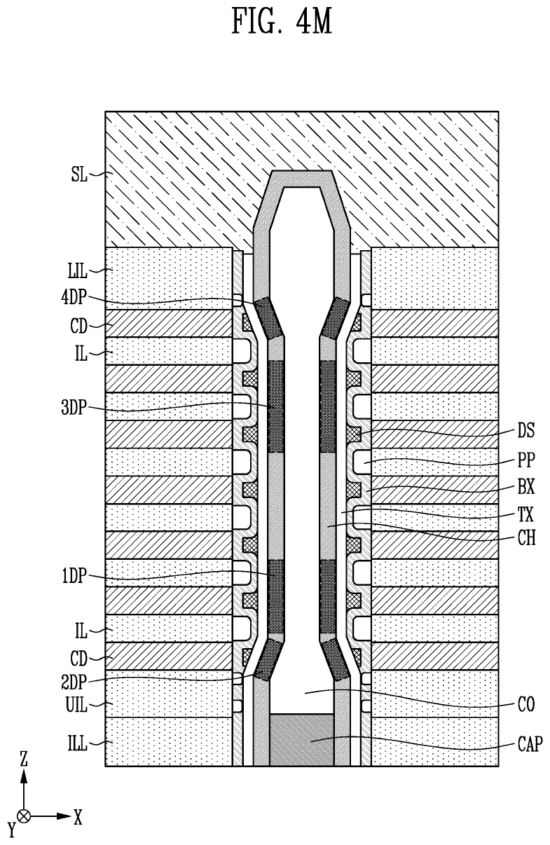

The process of injecting the first impurity, for example, boron B, into the first doped region 1DP may be performed independently of the process of injecting the second impurity, for example, phosphorus P or arsenic As, into the second doped region 2DP. A process of injecting impurities into different regions of the channel layer CH is described with reference to FIG. 4G and FIG. 4H.

Referring to the first graph GRAPH1, an additional impurity, for example, phosphorus P, is included in a region of the channel layer CH at a corresponding level with the capping layer CAP. During a process of forming the capping layer CAP, an impurity, for example, phosphorus P, may be doped into a lower section of the channel layer CH. For example, the impurity, for example, phosphorus P, included in the capping layer CAP may diffuse into regions of the channel layer CH that correspond to the drain dummy line DDL, the upper insulating layer UIL, and the insulating layer ILL. An upper surface of the capping layer CAP may be formed farther away from the conductive layers CD than shown in FIG. 3B. When the upper surface of the capping layer CAP is located farther away from the conductive layers CD, leakage caused by the drain dummy line DDL may be reduced.

Referring to the second graph GRAPH2 of FIG. 3B, the third doped region 3DP and the fourth doped region 4DP of the channel layer CH include a third impurity and a fourth impurity, respectively. The third impurity and the fourth impurity may be the same type of impurity. The third impurity and the fourth impurity may correspond to an element of group 15. For example, the third doped region 3DP and the fourth doped region 4DP may include phosphorus P or arsenic As. Because of the impurities injected into the third doped region 3DP and the fourth doped region 4DP of the channel layer CH, the resistance of the source dummy line SDL may be reduced, thereby improving the operation of the source select transistor SST.

The third impurity, for example, phosphorus P or arsenic As, injected into the third doped region 3DP is distributed at a level corresponding to the source select line SSL. The fourth impurity, for example, phosphorus P or arsenic As, injected into the fourth doped region 4DP is distributed at a level corresponding to the source dummy line SDL. According to a method of an impurity injection process, for example, energy, a depth at which each impurity is injected may vary.

The peak concentration of the third impurity, for example, phosphorus P or arsenic As, injected into the third doped region 3DP may be higher than the peak concentration of the fourth impurity, for example, phosphorus P or arsenic As, injected into the fourth doped region 4DP. Alternatively, unlike the embodiment shown in FIG. 3B, the peak concentration of the third impurity, for example, phosphorus P or arsenic As, injected into the third doped region 3DP may be similar to or lower than the peak concentration of the fourth impurity, for example, phosphorus P or arsenic As, injected into the fourth doped region 4DP. According to the method of the impurity injection process, for example, an angle or an injection dose, the distribution pattern and the concentration of each impurity may vary.

The third doped region 3DP does not coincide with the fourth doped region 4DP. For example, as illustrated in the second graph GRAPH2, a region where the third impurity, for example, phosphorus P or arsenic As, is injected does not coincide with a region where the fourth impurity, for example, phosphorus P or arsenic As, is injected. Alternatively, unlike as shown in FIG. 3B, the third doped region 3DP may coincide with the fourth doped region 4DP.

The process of injecting the third impurity, for example, phosphorus P or arsenic As, into the third doped region 3DP may be performed independently of the process of injecting the fourth impurity, for example, phosphorus P or arsenic As, into the fourth doped region 4DP. A process of injecting impurities into different regions of the channel layer CH is described with reference to FIG. 4K and FIG. 4L.

According to an embodiment of the present disclosure, when the first charge trap patterns DS1 of the charge trap patterns DS spaced apart from each other in the Z direction have an irregular shape, degradation of performance of the select transistors DST and SST may be prevented or mitigated. For example, the conductive layers CD at a similar level as the first charge trap patterns DS1 correspond to the dummy lines SDL and DDL, and impurities, for example, phosphorus P or arsenic As, are injected into the second sections P2 of the channel layer CH at a similar level as the dummy lines SDL and DDL, for example, the second doped region 2DP and the fourth doped region 4DP, thereby improving the off characteristics of the drain select transistor DST and improving the erase operation performance of the source select transistor SST.

FIG. 4A to FIG. 4M are diagrams illustrating a memory device formed utilizing a method of manufacturing the memory device according to an embodiment of the present disclosure.

Referring to FIG. 4A, the lower insulating layer LIL, sacrificial layers SF, the interlayer insulating layers IL, the upper insulating layer UIL, and a hard mask HM are sequentially stacked in the Z direction over a substrate SUB. The sacrificial layers SF are alternately stacked with the interlayer insulating layers IL in the Z direction. In an embodiment, the sacrificial layers SF and the interlayer insulating layers IL are referred to as a preliminary stack structure.

The interlayer insulating layers IL include an insulating material. For example, the interlayer insulating layers IL may include an oxide layer. The interlayer insulating layers IL may include a silicon oxide layer or an oxide material corresponding to the silicon oxide layer. The sacrificial layers SF may include a material that may be selectively removed during subsequent processes. The sacrificial layers SF include a material having different etch selectivity from the etch selectivity of the interlayer insulating layers IL. The sacrificial layers SF may include a nitride material. For example, the sacrificial layers SF may include a silicon nitride layer. The upper insulating layer UIL and the lower insulating layer LIL may include an oxide layer. Each of the upper insulating layer UIL and the lower insulating layer LIL may include a silicon oxide layer or an oxide material corresponding thereto. The hard mask HM may include the same material as the sacrificial layers SF.

Subsequently, an opening OP extending in the Z direction is formed in the preliminary stack structure. The opening OP extends through the hard mask HM, the upper insulating layer UIL, the sacrificial layers SF, the interlayer insulating layers IL, and the lower insulating layer LIL in the Z direction. The substrate SUB is exposed through the opening OP. For example, a section of the substrate SUB may be etched while the opening OP is formed. The opening OP may have an elongated shape extending in the Z direction. Side surfaces of the hard mask HM, the upper insulating layer UIL, the sacrificial layers SF, and the lower insulating layer LIL are exposed through the opening OP. A cross-sectional shape of the opening OP is not limited to the shape shown in FIG. 4A.

Referring to FIG. 4B, first sacrificial patterns SP1 are selectively formed on the sacrificial layers SF and the hard mask HM through the opening OP. The first sacrificial patterns SP1 are selectively deposited on the side surfaces of the sacrificial layers SF and the side surface of the hard mask HM. For example, the first sacrificial patterns SP1 may be layers that are grown from surfaces of the sacrificial layers SF and the hard mask HM.

The first sacrificial patterns SP1 include a material that is selectively deposited on a material included in the sacrificial layers SF. For example, the first sacrificial patterns SP1 may include a material that is selectively deposited on a nitride material. For example, the first sacrificial patterns SP1 may include silicon oxycarbide (SiOC).

The first sacrificial patterns SP1 are wider or have a greater thickness in the Z direction than the sacrificial layers SF and the hard mask HM. The thickness of the first sacrificial patterns SP1 is adjusted such that the consecutive first sacrificial patterns SP1 in the Z direction do not contact each other. As a result, the side surfaces of the interlayer insulating layers IL and the upper insulating layer UIL are exposed between consecutive first sacrificial patterns SP1 in the Z direction.

Referring to FIG. 4C, second sacrificial patterns SP2 are formed between the first sacrificial patterns SP1. The second sacrificial patterns SP2 are separated in the Z direction by the first sacrificial patterns SP1. The second sacrificial patterns SP2 are formed on the side surfaces of the interlayer insulating layers IL, the upper insulating layer UIL, and the lower insulating layer LIL. The second sacrificial patterns SP2 may include silicon.

For example, a sacrificial material is formed on an inner surface of the interlayer insulating layers IL, the upper insulating layer UIL, and the lower insulating layer LIL to fill spaces between the first sacrificial patterns SP1. For example, the sacrificial material covers the side surfaces of the interlayer insulating layers IL, the side surfaces of the upper and lower insulating layers UIL and LIL, and an inner surface of the substrate SUB that are exposed and the first sacrificial patterns SP1 (not shown). Some of the sacrificial material is removed to form the second sacrificial patterns SP2 as shown in FIG. 4C. For example, some of the sacrificial material formed on side surfaces of the first sacrificial patterns SP1, the inner surface of lower insulating layer LIL, and the inner surface of the substrate SUB are etched.

The second sacrificial patterns SP2 may include sacrificial patterns SP21, sacrificial patterns SP22, and a sacrificial pattern SP23. The sacrificial patterns SP21 are formed on the side surfaces of the interlayer insulating layers IL. The sacrificial patterns SP22 are separated from each other in the Z direction and disposed on the side surface of the upper insulating layer UIL. Because the length of the upper insulating layer UIL in the Z direction is greater than the length of the interlayer insulating layers IL in the Z direction, the sacrificial material filled between the first sacrificial patterns SP1 and adjacent to the upper insulating layer UIL may be over-etched. Each of the sacrificial patterns SP22 have smaller lengths in the Z direction and in the X direction than the length in the Z direction and length in the X direction of the sacrificial patterns SP21. The sacrificial pattern SP23 is formed on the side surface of the lower insulating layer LIL. When the sacrificial material is removed, the sacrificial pattern SP23 remains on the side surface of the lower insulating layer LIL.

Referring to FIG. 4D, the first sacrificial patterns SP1 are removed. An etch process may be performed to remove the first sacrificial patterns SP1. A dry etch process or a wet etch process may be performed. An isotropic etch process may be performed as the dry etch process. During the dry etch process, a source gas is used having a higher etch selectivity with respect to the etch selectivity of the first sacrificial patterns SP1 than with respect to the etch selectivity of the second sacrificial patterns SP2. During the wet etch process, an etchant is used having a higher etch selectivity with respect to the etch selectivity of first sacrificial patterns SP1 than with respect to the etch selectivity of the second sacrificial patterns SP2.

The second sacrificial patterns SP2 are oxidized to form the protruding patterns PP. The protruding patterns PP are formed on the side surfaces of the interlayer insulating layers IL, the upper insulating layer UIL, and the lower insulating layer LIL. Because the second sacrificial patterns SP2 are oxidized to form the protruding patterns PP, the protruding patterns PP have a greater volume than the second sacrificial patterns SP2. The protruding patterns PP may be silicon oxide layers because the second sacrificial patterns SP2 include silicon or a material including silicon.

The sacrificial patterns SP21 are oxidized to form the first protruding patterns PP1 described, for example, with reference to FIG. 3A. The sacrificial patterns SP22 are oxidized to form the second protruding patterns PP2 described, for example, with reference to FIG. 3A. Because the sacrificial patterns SP22 have a smaller size than the sacrificial patterns SP21, the second protruding patterns PP2 have a smaller size than the first protruding patterns PP1. The sacrificial pattern SP23 is oxidized to form the third protruding pattern PP3 described, for example, with reference to FIG. 3A. Because the sacrificial pattern SP23 has a smaller size than the sacrificial patterns SP21, the third protruding pattern PP3 is smaller than the first protruding patterns PP1.

The blocking insulating layer BX that extends along surfaces of the protruding patterns PP is formed. The blocking insulating layer BX is conformally formed on the side surface of the hard mask HM, the side surface of the upper insulating layer UIL, the protruding patterns PP, the side surfaces of the sacrificial layers SF, the side surface of the lower insulating layer LIL, and the inner surface of the substrate SUB. The blocking insulating layer BX may include an oxide layer.

The blocking insulating layer BX may have a serpentine structure that alternates curving inwardly and outwardly along the protruding patterns PP. Recesses may be formed on an inner surface of the blocking insulating layer BX. The recesses may be formed between the protruding patterns PP. Because the protruding patterns PP2 and PP3 are smaller than the first protruding patterns PP1, a one or more of the recesses may have an asymmetric shape. For example, recesses located across from a top sacrificial layer SF and a bottom sacrificial layer SF in the X or horizontal direction may have an asymmetric shape. A recess located between the second protruding patterns PP2 is smaller than the other recesses.

Referring to FIG. 4E, the charge trap patterns DS are formed between the protruding patterns PP. The charge trap patterns DS are spaced apart in the Z direction. The charge trap patterns DS are formed in the recesses disposed in the blocking insulating layer BX. For example, a charge trap material may be formed to entirely cover the blocking insulating layer BX. The charge trap material may include a nitride layer. The charge trap material may fill all recesses within the blocking insulating layer BX. A segment of the charge trap material formed on a bottom and a side surface of the blocking insulating layer BX is removed. A dry etch process may be performed to remove the segment of the charge trap material. For example, an anisotropic dry etch process may be performed such that the charge trap material remains in the recesses of the blocking insulating layer BX. During the anisotropic dry etch process, a source gas is used having a higher etch selectivity with respect to the etch selectivity of the charge trap material than with respect to the etch selectivity of the blocking insulating layer BX. The charge trap material remaining in the recesses of the blocking insulating layer BX forms the charge trap patterns DS.

The second charge trap patterns DS2 are formed between the first protruding patterns PP1 that have a similar size and shape. Because the first protruding patterns PP1 has a similar size and shape, the second charge trap patterns DS2 have a symmetrical shape. A symmetrical shape may refer to a structure that is symmetrical about an XY plane.

The first charge trap pattern DS1 formed between the first protruding pattern PP1 and the second protruding pattern PP2 has an asymmetric shape. Because the second protruding pattern PP2 is smaller than the first protruding pattern PP1, the inner surface of the first charge trap pattern DS1 is inclined with respect to the Z direction. For example, a side surface of the first charge trap pattern DS1 has first slope relative to the Z direction.

The first charge trap pattern DS1 formed between a lowermost first protruding pattern PP1 and the third protruding pattern PP3 also has an asymmetric shape. Because the third protruding pattern PP3 is smaller than the first protruding pattern PP1, the inner surface of the first charge trap pattern DS1 is inclined with respect to the Z direction.

A charge trap pattern is not formed between the second protruding patterns PP2. Because the second protruding patterns PP2 are smaller than the first protruding patterns PP1, a charge trap pattern might not be formed due to lack of sufficient space between the second protruding patterns PP2.

Referring to FIG. 4F, the tunneling layer TX, the channel layer CH, the core pillar CO, and the capping layer CAP are sequentially formed within the blocking insulating layer BX. The tunneling layer TX contacts the charge trap patterns DS and the blocking insulating layer BX. The tunneling layer TX is conformally formed along the side surfaces of the charge trap patterns DS and the blocking insulating layer BX. The channel layer CH contacts the inner surface of the tunneling layer TX. The channel layer CH extends primarily in the Z direction. The channel layer CH is conformally formed on the side surface of the tunneling layer TX. The channel layer CH includes the first sections P1 of FIG. 3A extending in the Z direction and the second sections P2 of FIG. 3A having the second slope of the first charge trap pattern DS1. The core pillar CO contacts the inner surface of the channel layer CH and fills the volume within the channel layer CH. The core pillar CO is surrounded by the channel layer CH. The capping layer CAP contacts the channel layer CH and the top of the core pillar CO. The capping layer CAP contacts an upper surface of the core pillar CO and the inner surface of the channel layer CH. The shapes of the tunneling layer TX, the channel layer CH, the core pillar CO, and the capping layer CAP are not limited to the shapes shown in FIG. 4F. The tunneling layer TX may include an oxide layer. The channel layer CH and the capping layer CAP may include a doped silicon layer or an undoped silicon layer. The core pillar CO may include an insulating layer or a conductive layer.

Referring to FIG. 4G, a first impurity injection process is performed including injecting the first impurity into a section of the channel layer CH, for example, the first section P1 of FIG. 3A. The first impurity injection process may include injecting the first impurity, for example, an element of group 13 such as boron B, into the first doped region 1DP of the channel layer CH.

In an embodiment, the first impurity injection process is performed in the Z direction or without a tilt. In an embodiment, the first impurity injection process may be performed with a tilt at an angle of 30 to 80 degrees with respect to the Z axis. When impurities are injected with a tilt at a predetermined angle, the impurities are divided by N and injected N times, rotating from N different directions. For example, when an impurity injection process is performed four times at a tilt angle of 30 degrees, the impurities may be injected from four directions, each at the tilt angle of 30 degrees relative to the Z axis, specifically along the X, Y, −X, and −Y axes. The −X and −Y axes represent the opposite directions of the X and Y axes, respectively. When the first impurity injection process is performed with a tilt, the distribution of impurity concentration shows a more abrupt incline than shown in the first graph GRAPH1 of FIG. 3B.

The first impurity injection process may be controlled such that impurities are injected to a depth corresponding to a second sacrificial layer SF, for example, the sacrificial layer SF corresponding to the drain select line DSL of FIG. 3A, from the top of FIG. 4G.

Referring to FIG. 4H, a second impurity injection process is performed including injecting the second impurity into a section of the channel layer CH, for example, the second section P2 of FIG. 3A. The second impurity injection process may include injecting the second impurity, for example, an element of group 15 such as phosphorus P or arsenic As, into the second doped region 2DP of the channel layer CH. In an embodiment, the second impurity injection process may be performed with a tilt at an angle of 0 to 50 degrees. When impurities are injected with a tilt at a predetermined angle, the impurities are divided into several divisions such as halves, quarters, or eighths and injected from different directions over multiple time periods, such as two time periods, four time periods, or eight time periods.

The projection range or depth of the second impurity injection process corresponds to a depth of an inclined surface of the channel layer CH, for example, the second section P2 of FIG. 3A or 2DP in FIG. 4H. The second impurity injection process may be controlled such that impurities are injected to a depth including the inclined surface of the channel layer CH or the first charge trap pattern DS1.

The second impurity injection process is performed subsequent to performing the first impurity injection process as shown in the progression from FIG. 4G to FIG. 4H. The scope of the present disclosure is not limited to performing the first impurity injection process prior to performing the second impurity injection process as described. For example, the second impurity injection process may be performed prior to performing the first impurity injection process.

Referring to FIG. 4I, the sacrificial layers SF are replaced by the conductive layers CD. For example, an etch process is performed to remove the sacrificial layers SF. Because the sacrificial layers SF are formed between the interlayer insulating layers IL, an isotropic dry etch process or a wet etch process may be performed as the etch process. The sacrificial layers SF are removed resulting in openings between the interlayer insulating layers IL. The conductive layers CD are formed in the openings. The conductive layers CD may include at least one of tungsten W, cobalt Co, nickel Ni, molybdenum Mo, silicon Si, and polysilicon poly-Si. The conductive layers CD may include various other conductive materials. The conductive layers CD and the interlayer insulating layers IL are referred to as a stack structure.

The hard mask HM is replaced by the insulating layer ILL. For example, the hard mask HM is removed by etching and is replaced at the same location with the insulating layer ILL. The insulating layer ILL may include an oxide layer. In another example, the hard mask HM is not removed and remains as the insulating layer ILL.

Subsequently, the stack structure may be flipped or inverted in the Z direction and bonded to and disposed on a peripheral circuit structure (not shown). The peripheral circuit structure (not shown) may be disposed under the insulating layer ILL in an embodiment of the present disclosure.

Referring to FIG. 4J, the substrate SUB is removed. The substrate SUB is etched, for example, after the stack structure is inverted and bonded to the peripheral circuit structure. For example, an isotropic wet etch process may be performed to etch the substrate SUB. Because the substrate SUB is removed, a section of the blocking insulating layer BX formed on a surface of the is exposed.

A section of the blocking insulating layer BX and a section of the tunneling layer TX are removed. Because the substrate SUB is removed, an exposed section of the blocking insulating layer BX may be etched and removed, and an exposed section of the tunneling layer TX may be etched and removed. To selectively etch the blocking insulating layer BX and the tunneling layer TX, an isotropic wet etch process may be performed. Because the section of the blocking insulating layer BX and the section of the tunneling layer TX are removed, a section of the channel layer CH is exposed.

In an embodiment, the blocking insulating layer BX is over-etched. As a result, an upper surface of the blocking insulating layer BX is located lower than an upper surface of the lower insulating layer LIL. The tunneling layer TX is also over-etched in this example. As a result, an upper surface of the tunneling layer TX is located lower than the upper surface of the blocking insulating layer BX and the upper surface of the lower insulating layer LIL. FIG. 4J illustrates one example that does not limit the scope of the present disclosure, and the extent of etching of the blocking insulating layer BX and the tunneling layer TX may vary from FIG. 4J as long as the channel layer CH is exposed.

Referring to FIG. 4K, a third impurity injection process is performed including injecting the third impurity into a section of the channel layer CH, for example, the first section P1 of FIG. 3A. The third impurity injection process may include injecting the third impurity, for example, an element of group 15 such as phosphorus P or arsenic As, into the third doped region 3DP of the channel layer CH. In an embodiment, the third impurity injection process may be performed with a tilt at an angle of 0 to 90 degrees. When impurities are injected with a tilt at a predetermined angle, the impurities are divided into several divisions such as halves, quarters, or eighths and injected from different directions and over multiple time periods, such as two time periods, four time periods, or eight time periods.

The third impurity injection process may be controlled such that impurities are injected to a depth corresponding to a second conductive layer CD, for example, the source select line SSL of FIG. 3A, from the top of FIG. 4K.

Because the third impurity injection process is performed by injecting toward the channel layer CH protruding in an upward direction as shown in FIG. 4K, the third impurity injection process may advantageously address shadow effect resulting in an uneven distribution of impurities.

Referring to FIG. 4L, a fourth impurity injection process is performed including injecting the fourth impurity into a section of the channel layer CH, for example, the second section P2 of FIG. 3A. The fourth impurity injection process may include injecting the fourth impurity, for example, an element of group 15 such as phosphorus P or arsenic As, into the fourth doped region 4DP of the channel layer CH. In an embodiment, the fourth impurity injection process may be performed with a tilt at an angle of 0 to 90 degrees or 0 to 50 degrees.

Referring to the peak concentration of the impurities in the second graph GRAPH2 of FIG. 3B, the dose during the fourth impurity injection process is smaller than the dose during the third impurity injection process. Referring to the injection distances shown in the second graph GRAPH2 of FIG. 3B, the energy of the fourth impurity injection process is smaller than the energy of the third impurity injection process.

The projection range or depth of the fourth impurity injection process corresponds to a depth of an inclined surface of the channel layer CH, for example, the second section P2 of FIG. 3A. The fourth impurity injection process may be controlled such that impurities are injected to a depth including the inclined surface of the channel layer CH or the first charge trap pattern DS1.

The fourth impurity injection process is performed subsequent to performing the third impurity injection process as shown in the progression from FIG. 4K to FIG. 4L. The scope of the present disclosure is not limited to performing the first impurity injection process prior to performing the second impurity injection process as described. For example, the fourth impurity injection process may be performed prior to performing the third impurity injection process.

The memory device according to an embodiment of the present disclosure has a wafer bonding structure. After the first impurity injection process and the second impurity injection process are performed in a region near to the drain select transistor DST, the stack structure may be inverted and the third impurity injection process and the fourth impurity injection process may be performed in a region near the source select transistor SST. For example, impurities may be doped into the doped regions 1DP to 4DP using an implant process. Compared to a diffusion process, the implant process may be performed at a lower temperature. The concentration, distribution, thickness, and other characteristics of impurities may be adjusted more precisely during the implant process than during the diffusion process. Accordingly, the performance of the select transistors DST and SST may be improved by including the first to fourth impurities in the channel layer CH according to an embodiment of the present disclosure.

Referring to FIG. 4M, the source line SL is formed to cover the channel layer CH. The source line SL covers the exposed section of the channel layer CH exposed. The source line SL contacts a surface of the channel layer CH.

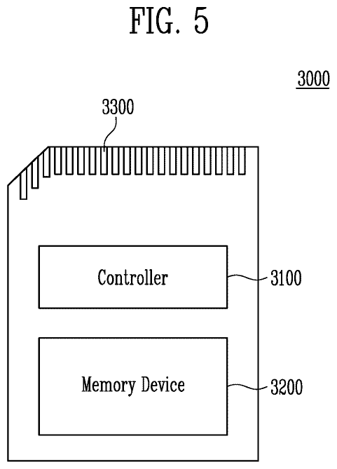

FIG. 5 is a diagram illustrating a memory card system 3000 including a memory device according to an embodiment of the present disclosure.

Referring to FIG. 5, the memory card system 3000 includes a controller 3100, a memory device 3200, and a connector 3300.

The controller 3100 is coupled to the memory device 3200. The controller 3100 is configured to access the memory device 3200. For example, the controller 3100 is configured to control program operation, read operation, and erase operation of the memory device 3200, or control background operation. The controller 3100 is configured to provide an interface between the memory device 3200 and a host. The controller 3100 is configured to run firmware that controls the memory device 3200. For example, the controller 3100 may include components such as a Random Access Memory (RAM), a processing unit, a host interface, a memory interface, and an error corrector.

The controller 3100 communicates with an external device through the connector 3300. The controller 3100 communicates with the external device, for example, the host, according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnect (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be configured according to at least one of the above communication protocols.

The memory device 3200 includes a plurality of memory cells and is configured in a similar manner as the memory device 100 shown in FIG. 1 and FIG. 3B.

The controller 3100 and the memory device 3200 are integrated into a single semiconductor device to form a memory card. For example, the controller 3100 and the memory device 3200 may be integrated into a single semiconductor device to form a memory card such as a personal computer (PC) card in the form of a Personal Computer Memory Card International Association (PCMCIA) card, a Compact Flash (CF) card, a Smart Media Card (SM and SMC), a memory stick, a Multi-Media Card (MMC, RS-MMC, MMCmicro, or eMMC), a Secure Digital (SD) card (SD, miniSD, microSD, or SDHC), and a Universal Flash Storage (UFS).

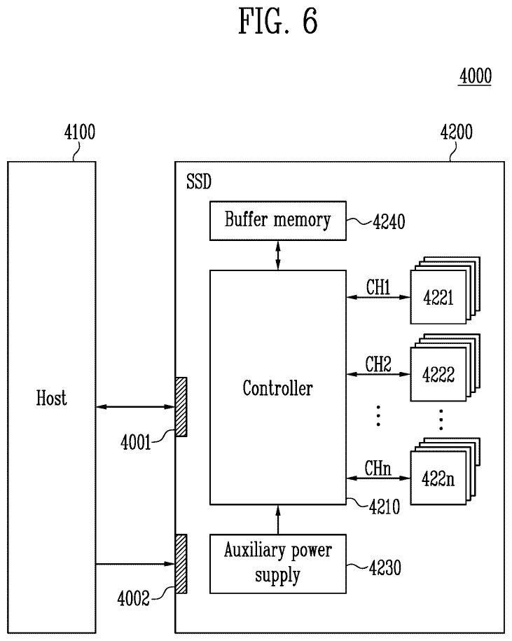

FIG. 6 is a diagram illustrating a solid state drive (SSD) system 4000 including a memory device according to an embodiment of the present disclosure.

Referring to FIG. 6, the SSD system 4000 may include a host 4100 and an SSD 4200. The SSD 4200 exchanges signals with the host 4100 through a signal connector 4001 and receives power through a power connector 4002. The SSD 4200 includes a controller 4210, a plurality of memory devices 4221 to 422n, an auxiliary power supply 4230, and a buffer memory 4240.

The controller 4210 controls the plurality of memory devices 4221 to 422n in response to signals received from the host 4100. For example, the signals may be based on an interface between the host 4100 and the SSD 4200. For example, the signals may be configured or constructed according to at least one of a plurality of interfaces such as Universal Serial Bus (USB), Multi-Media Card (MMC), embedded MMC (eMMC), Peripheral Component Interconnect (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe interfaces.

Each of the plurality of memory devices 4221 to 422n includes a plurality of memory cells configured to store data. Each of the plurality of memory devices 4221 to 422n are configured in the similar manner as the memory device 100 shown in FIG. 1 and FIG. 3B. The plurality of memory devices 4221 to 422n communicates with the controller 4210 through channels CH1 to CHn.

The auxiliary power supply 4230 is coupled to the host 4100 through a power connector 4002. The auxiliary power supply 4230 receives power from the host 4100 and may be charged. When the supply of power from the host 4100 is not smooth or consistent, the auxiliary power supply 4230 provides power to the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 is buffer memory for the SSD 4200. For example, the buffer memory 4240 temporarily stores data received from the host 4100 or data received from the plurality of memory devices 4221 to 422n, or temporarily stores metadata, for example, mapping tables, of the memory devices 4221 to 422n. The buffer memory 4240 may include one or more volatile memories such as DRAM, SDRAM, DDR SDRAM, and LPDDR SDRAM or non-volatile memories such as FRAM, ReRAM, STT-MRAM, and PRAM.

According to embodiments of the present disclosure, the performance of a select transistor may be improved at a cell plug having charge trap patterns separated from each other in, for example, a vertical direction.

Although the detailed embodiments are described in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A memory device comprising:
a stack structure including a plurality of conductive layers alternately stacked with a plurality of interlayer insulting layers in a first direction;
a channel layer extending through the stack structure; and
a plurality of charge trap patterns located between the channel layer and the plurality of conductive layers and spaced apart in the first direction;
wherein a side surface of a first charge trap pattern among the plurality of charge trap patterns has a first slope with respect to the first direction,
wherein the channel layer includes a first section extending in the first direction and a second section having the first slope;
wherein the first section of the channel layer includes a first impurity; and
wherein the second section of the channel layer includes a second impurity.

2. The memory device of claim 1, wherein a diameter of the second section of the channel layer is greater than a diameter of the first section of the channel layer in a plane including a second direction perpendicular to the first direction.

3. The memory device of claim 1, wherein the plurality of charge trap patterns has a ring shape surrounding the channel layer.

4. The memory device of claim 1, further comprising a plurality of protruding patterns, each protruding pattern protruding from a side surface of a different one of the plurality of interlayer insulating layers in a second direction perpendicular to the first direction;
wherein each of the plurality of charge trap patterns is located between consecutive protruding patterns in the first direction.

5. The memory device of claim 4, further comprising:
a blocking insulating layer extending between the plurality of protruding patterns and the plurality of charge trap patterns;
a tunneling layer contacting the plurality of charge trap patterns and the blocking insulating layer and surrounding a side surface of the channel layer;
a core pillar surrounded by the channel layer; and
a capping layer contacting a surface of the core pillar and an inner surface of the channel layer.

6. The memory device of claim 1, wherein the first impurity is a different type of impurity than a type of the second impurity.

7. The memory device of claim 6, wherein the first impurity includes an element of group 13 of the periodic table, and the second impurity includes an element of group 15 of the periodic table.

8. The memory device of claim 1, wherein the first impurity is a same type of impurity as a type of the second impurity.

9. The memory device of claim 8, wherein the first impurity and the second impurity include an element of group 15 of the periodic table.

10. The memory device of claim 1,
wherein the plurality of conductive layers include a dummy line and a select line;
wherein the first section of the channel layer is located at a level in the first direction corresponding to a level of the select line; and
wherein the second section of the channel layer is located at a level in the first direction corresponding to a level of the dummy line.

11. The memory device of claim 1,
wherein the plurality of conductive layers include a drain dummy line, a drain select line, a plurality of word lines, a source select line, and a source dummy line;
wherein the first section of the channel layer is located at a level corresponding to a level of one of the drain select line and the source select line; and
wherein the second section of the channel layer is located at a level corresponding to a level of one of the drain dummy line and the source dummy line.

12. A method of manufacturing a memory device, the method comprising:
forming, on a substrate, a stack structure including a plurality of sacrificial layers alternately stacked with a plurality of interlayer insulating layers in a first direction;
forming an opening extending in the first direction in the stack structure, exposing inner surfaces of the plurality of sacrificial layers and inner surfaces of the plurality of interlayer insulating layers;
forming a plurality of charge trap patterns spaced apart in the first direction, wherein a side surface of a first charge trap pattern among the plurality of charge trap patterns has a first slope with respect to the first direction, and wherein each of the plurality of charge trap patterns is disposed between the inner surfaces of a different one of the plurality of sacrificial layers in the first direction;
forming a channel layer extending in the first direction between the inner surfaces of the plurality of sacrificial layers and the inner surfaces of plurality of interlayer insulating layers, wherein the channel layer includes a first section extending in the first direction and a second section having the first slope;
injecting a first impurity into the first section of the channel layer; and
injecting a second impurity into the second section of the channel layer, wherein the second impurity is different from the first impurity.

13. The method of claim 12, further comprising:
forming a plurality of protruding patterns on the inner surfaces of the plurality of interlayer insulating layers; and
forming a blocking insulating layer extending along surfaces of the plurality of protruding patterns.

14. The method of claim 12, further comprising forming a tunneling layer contacting the plurality of charge trap patterns.

15. The method of claim 12, further comprising:
forming a core pillar surrounded by the channel layer; and
forming a capping layer contacting a surface of the core pillar and an inner surface of the channel layer.

16. The method of claim 12, further comprising:
replacing the plurality of sacrificial layers of the stack structure with a plurality of conductive layers;
bonding the stack structure to a peripheral circuit structure; and
exposing a section of the channel layer by removing the substrate.

17. The method of claim 16, wherein the channel layer further includes a third section extending in the first direction and a fourth section having a second slope with respect to the first direction, and
wherein the method further comprises:
injecting a third impurity into the third section of the channel layer; and
injecting a fourth impurity into the fourth section of the channel layer.

18. The method of claim 17, wherein the third impurity is a same type of impurity as the fourth impurity.

19. The method of claim 17, further comprising, forming a source line covering the exposed section of the channel layer.

20. A memory device comprising:
a stack structure including a plurality of conductive layers alternately stacked with a plurality of interlayer insulting layers in a first direction;
a channel layer extending through the stack structure and including a first section including a first impurity and extending in the first direction and a second section including a second impurity and disposed at a first slope with relative to the first direction; and
a charge trap pattern located between the channel layer and a first conductive layer of the plurality of conductive layers, wherein a side surface of the charge trap pattern is parallel to the second section.
